(19) United States
(12) Patent Application Publication
(10) Pub. No.: US 2024/0112731 A1
(43) Pub. Date: Apr. 4, 2024

(54) MEMORY ARRAY COMPRISING A FERROELECTRIC DATA STORAGE ELEMENT

(71) Applicant: Intel Corporation, Santa Clara, CA (US)

(72) Inventors: Sou-Chi Chang, Portland, OR (US); Chia-Ching Lin, Portland, OR (US); Saima Siddiqui, HIllsboro, OR (US); Sarah Atanasov, Beaverton, OR (US); Bernal Granados Alpizar, Beaverton, OR (US); Uygar Avci, Portland, OR (US)

(73) Assignee: Intel Corporation, Santa Clara, CA (US)

(21) Appl. No.: 17/957,957

(22) Filed: Sep. 30, 2022

(51) Int. Cl. G11C 13/00; G11C 11/22; H01L 45/00

(52) U.S. Cl. CPC G11C 13/0069; G11C 11/22; G11C 13/0007; G11C 13/0026; G11C 13/0028; G11C 13/004; H01L 45/1253; H01L 45/146; H01L 45/1608

(57) ABSTRACT

Techniques and mechanisms for operating a ferroelectric (FE) circuit element as a cell of a crossbar memory array. In an embodiment, the crossbar memory array comprises a bit line, a word line, and a data storage cell which includes a circuit element that extends to each of the bit line and the word line. The data storage cell is a FE circuit element which comprises terminals, each at a different respective one of the bit line or the word line, and one or more material layers between said terminals. One such layer comprises a FE nitride or a FE oxide. The FE circuit element is operable to selectively enable, or disable, operation as a diode. In another embodiment, the memory array is coupled to circuitry which corresponds a given mode of operation of the FE circuit element to a particular data bit value.

### BACKGROUND

### 1. Technical Field

This disclosure generally relates to resistive memory devices and more particularly, but not exclusively, to a crossbar memory which includes a ferroelectric diode as a data storage element.

### 2. Background Art

Resistance-switching non-volatile memory (NVM), also known as ReRAM or RRAM, is a possible replacement for flash memory and other charge-storage-based forms of nonvolatile memory. Resistance-switching cells repeatedly change their resistance between at least two distinguishable values in response to a signal, such as an applied electric, magnetic, thermal, chemical, optical, or combination stimulus. In the absence of the resistance-changing stimulus, and even in the absence of supplied power, the cell retains its last programmed resistance, making it usable as a static, or nonvolatile, memory element.

In the simplest case, a ReRAM cell switches between two resistance values, a low-resistance state (LRS) and a high-resistance state (HRS). Such a cell can store one bit of data by assigning one state to “logic-zero” and the other to “logic-one.” The cell is written (its resistance is changed) by the application of a write signal (e.g., voltage, current, heat, light, etc.) that is at or above a write-threshold strength. The cell is read (its resistance is sensed without being changed) by applying a voltage (or current) that is below the write-threshold strength, measuring the output current (or voltage), and applying Ohm's law (R=V/I, where R is resistance, V is voltage, and I is current.

Cells that can be repeatedly switched between more than two resistance states have been demonstrated. Such cells may store multiple bits of data. Although NVM is a leading application of resistance-switching cells, the cells may also be used for other switching applications; for example, as a threshold switch or a logic element that keeps its state when the device is powered down and powered back up.

### BRIEF DESCRIPTION OF THE DRAWINGS

The various embodiments of the present invention are illustrated by way of example, and not by way of limitation, in the figures of the accompanying drawings and in which:

FIG. 1 is a functional block diagram illustrating elements of a device comprising a cross bar memory array according to an embodiment.

FIG. 2 is a cut-away perspective view diagram illustrating elements of a memory array comprising a ferroelectric circuit element which operates as a memory cell according to an embodiment.

FIGS. 3A through 3D are cross-sectional side view diagrams each illustrating elements of a respective ferroelectric circuit element to provide functionality of a memory cell according to a corresponding embodiment.

FIG. 4 is a flow diagram illustrating elements of a method to provide a ferroelectric resistive memory element of a cross bar memory array according to an embodiment.

FIG. 5 is a graph illustrating current conduction characteristics of a ferroelectric resistive memory element according to an embodiment.

FIG. 6 is a cut-away perspective view diagram illustrating elements of multi-layer memory device comprising a ferroelectric resistive memory cells according to an embodiment.

FIG. 7 is a functional block diagram illustrating a computing device in accordance with one embodiment.

FIG. 8 is a functional block diagram illustrating an exemplary computer system, in accordance with one embodiment.

### DETAILED DESCRIPTION

Embodiments discussed herein variously provide techniques and mechanisms for operating a ferroelectric (FE) circuit element as a cell of a crossbar memory array. In various existing ReRAM memory devices, an individual memory cell comprises both a resistive memory element and either a selector or a transistor. The inclusion of such a selector or a transistor in a memory cell contributes significantly to cell size, which impacts attempts to reduce cell complexity and/or scale. By contrast, some embodiments provide a single FE circuit element which is to operate as a memory cell of a crossbar memory array—e.g., wherein the memory cell omits any additional circuit element or other structure which is to further provide selection functionality.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including a memory array.

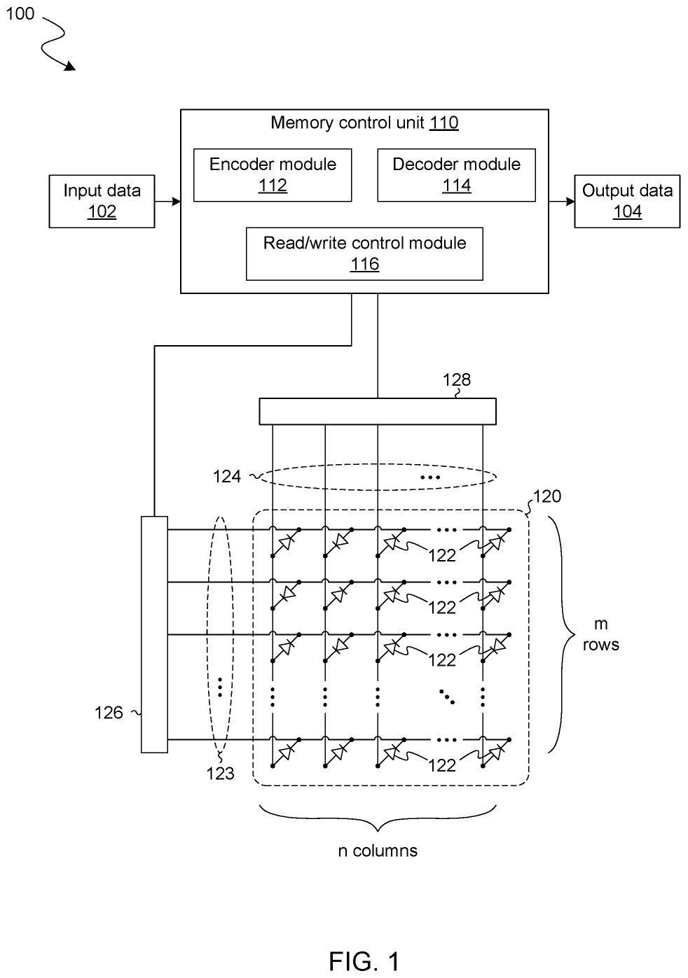

FIG. 1 illustrates features of a data storage device 100 which includes a crossbar memory comprising ferroelectric resistive memory elements according to an embodiment. Device 100 is an example of an embodiment wherein a ReRAM cell includes a ferroelectric circuit element comprising two terminals, each of which extends to, and is electrically coupled with, a different respective one of a row conductor (referred to herein as a “word line”) or a column conductor (referred to herein as a “bit line”). A given one such ferroelectric circuit element is (re)configurable to selectively operate as a diode for representing a given bit of data.

As shown in FIG. 1, device 100 comprises a memory array 120 and a memory control unit 110 which is coupled to facilitate access to memory array 120. For example, memory control unit 110 controls operations for storing data to and/or retrieving data from memory array 120, which comprises a m-by-n arrangement of cells 122. In the example embodiment shown, memory control unit 110 comprises an encoder module 112 comprising integrated circuitry for encoding data which is to be written to memory array 120, and a decoder module 114 comprising integrated circuitry for decoding data that has been read from memory array 120. Furthermore, memory control unit 110 comprises a read/write control module 116 that is to control operations of reading data from the memory array 120 and writing data to the memory array 120. In an illustrative scenario according to one embodiment, memory control unit 110 encodes input data 102 and stores the encoded data into the memory array 120. The memory control unit 110 also reads out the encoded data stored in the memory array 120, decodes the data to recover the original bits in the input data 102, and transmits the decoded data as output data 104.

In the example embodiment shown, device 100 includes memory control unit 110 and memory array 120. In other embodiments, device 100 includes memory array 120 and omits (but accommodates coupling to operate with) memory control unit 110. In any regard, the illustrative memory array 120 includes a first set of “word line” conductors (e.g., wires), and a second sets of “bit line” conductors. For example, the m×n memory array 120 includes m word lines 123 and n bit lines 124 in a circuit plane. In one such embodiment, each of the m word lines cross each of the n bit lines, wherein cells 122 are each located at the different respective crossing point of a corresponding word line and bit line pair. The cross points of the word lines 123 and the bit lines 124 thus comprise a total of m×n cells. The reading and writing of individual bits of data to the cells 122 involves the application of voltages by row driver circuitry 126 and column driver circuitry 128.

In various embodiments, a given one of cells 122 comprises a pillar structure which extends to each of a corresponding one of word lines 123 and a corresponding one of bit lines 124. For example, a first cell of cells 122 corresponds to a first word line of word lines 123, and also corresponds to a first bit line of bit lines 124—i.e., wherein the first cell is at a cross point of the first word line and the first bit line. In one such embodiment, the pillar structure of the first cell provides a FE circuit element which comprises both a first electrode structure which extends to the first word line, and a second electrode structure which extends to the first bit line. The first electrode structure and the second electrode structure provide, respectively, a first terminal and a second terminal of the FE circuit element—e.g., wherein the FE circuit element is coupled at the first word line via the first terminal, and is further coupled at the first bit line via the second terminal.

In an embodiment, the FE circuit element further comprises a layer of material which is between the first terminal and the second terminal. The material comprises a ferroelectric (FE) nitride, or a FE oxide, which facilitates operation of the pillar structure as a ferroelectric diode. In the example embodiment of data storage device 100, the FE circuit elements of cells 122 are represented symbolically as diodes, wherein a (re)configurable orientation of a given one such diode is based on the selective provisioning of a polarization orientation and/or other suitable material characteristic of the circuit element's FE material. For example, one polarization orientation of a given circuit element results in that circuit element being configured in a “diode” mode of operation which enables conductivity to one of a corresponding word line or a corresponding bit line. By contrast, a different polarization orientation (e.g., different in degree and/or direction) of the FE material results in the circuit element being configured in an alternative mode which disables such conductivity to that one of the corresponding word line or the corresponding bit line. For example, the alternative mode is a different diode mode which instead enables conductivity to the other of the corresponding word line or the corresponding bit line. In another embodiment, the alternative mode is an “off” (e.g., an open circuit) mode which disables any conductivity via the circuit element.

By providing such a ferroelectric diode functionality at a cell of a crossbar memory array, some embodiments variously avoid the need for a selector structure or a transistor, which enables a more compact memory cell design. In an illustrative scenario according to one such embodiment, all the word lines 123 and bit lines 124 are held at a voltage Vw/2, which is half of a write voltage Vw. To write to the selected first cell, the voltage of the corresponding first word line is raised to Vw and the voltage of the corresponding first bit line is lowered to 0 so that the voltage drop across the selected first cell is the full write voltage Vw.

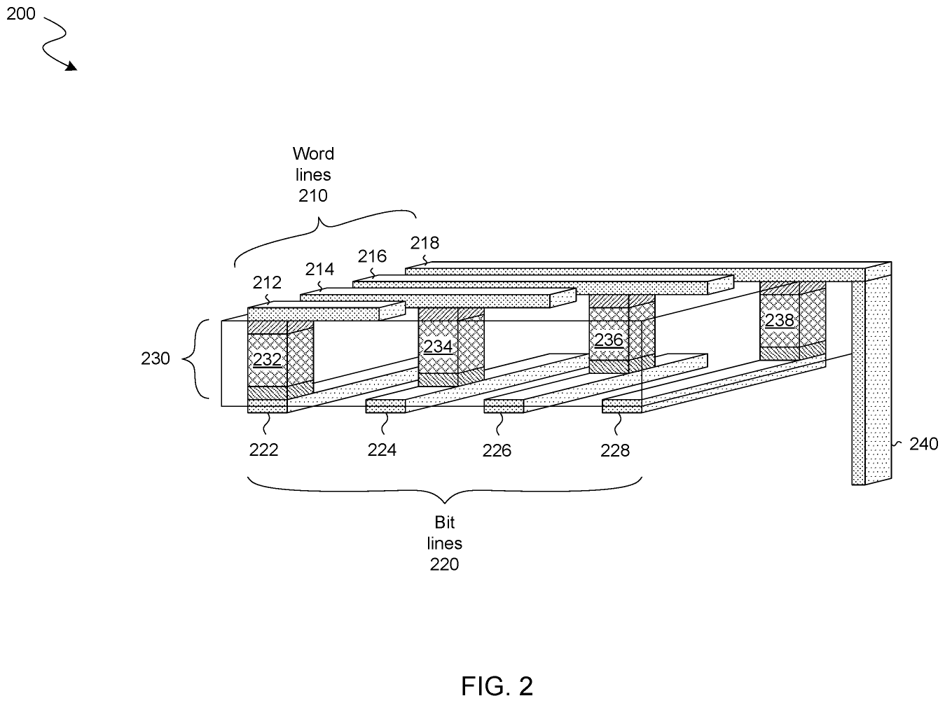

FIG. 2 shows a cut-away perspective view of a crossbar memory array 200 according to one embodiment. Crossbar memory array 200 illustrates an example of an embodiment wherein ferroelectric (FE) circuit elements are variously coupled each to provide a different respective resistive memory element. A given one such FE circuit element is (re)configurable to selectively provide functionality of a diode. In one such embodiment, crossbar memory array 200 provides functionality such as that of memory array 120.

As shown in FIG. 2, crossbar memory array 200 comprises a set of word lines 210 which, for example, are generally in parallel with respect to each other. Additionally, crossbar memory array 200 comprises a set of bit lines 220 which are generally perpendicular to, and cross, the word lines 210. Programmable FE circuit elements 230 of crossbar memory array 200 are variously located at corresponding cross points which are each between a respective one of word lines 210 and a respective one of bit lines 220. By way of illustration and not limitation, a FE device 232 is at a cross point between a word line 212 and a bit line 222—e.g., wherein another FE device 234 is at a cross point between a word line 214 and a bit line 224. Furthermore, a FE device 236 is at a cross point between a word line 216 and a bit line 226, wherein another FE device 238 is at a cross point between a word line 218 and a bit line 228. The FE circuit elements 230 are each to function as a resistive memory element.

In an embodiment, FE device 232 (or any other of FE devices 230) is a circuit element which comprises a pillar structure including both a first electrode structure which is at one end of the pillar structure, and a second electrode structure which is at an opposite end of the pillar structure. The first electrode structure and the second electrode structure provide, respectively, a first terminal and a second terminal of the circuit element—e.g., wherein the circuit element is coupled at the word line 212 via the first terminal, and is further coupled at the bit line 222 via the second terminal.

In one illustrative embodiment, a given one of the first electrode structure or the second electrode structure comprises any of various suitable metals including (but not limited to) titanium (Ti), tungsten (W), tantalum (Ta), ruthenium (Ru), iridium (Jr), aluminum (Al), copper (Cu), cobalt (Co), chromium (Cr), molybdenum (Mo), nickel (Ni), gold (Au), or platinum (Pt). For example, a stoichiometry of one such electrode structure is substantially the same as that of tantalum nitride (TaN) or titanium nitride (TiN). Additionally or alternatively, a given one of the first electrode structure or the second electrode structure comprises any of various suitable oxide semiconductors including (but not limited to) indium (In), gallium (Ga), zinc (Zn), tungsten (W), strontium (Sr), titanium (Ti), or the like. By way of illustration and not limitation, a stoichiometry of a given one of the first electrode structure or the second electrode structure is substantially equal to a stoichiometry of indium gallium zinc oxide (IGZO), indium tungsten oxide (IWO), strontium titanate (STO), indium(III) oxide (I₂O₃), or Nb-doped STO (for example).

In an embodiment, the pillar structure of FE device 232 further comprises one or material layers including at least a layer of FE material which is between the first terminal and the second terminal. The FE material comprises a FE nitride, or a FE oxide, which facilitates operation of the pillar structure as a ferroelectric diode. In one such embodiment, the FE material is a FE nitride such as one which includes one or more of aluminum (Al), scandium (Sc), gallium (Ga), and nitrogen (N)— e.g., wherein a stoichiometry of the FE nitride is substantially equal to a stoichiometry of aluminum scandium nitride (AlScN). In various embodiments, a thickness of the FE nitride is in a range of 3 nanometers (nm) to 30 nm.

In another embodiment, the FE material is a FE oxide such as one which includes hafnium (Hf), and oxygen (O), as well as any of various dopants including (for example) one of silicon (Si), germanium (Ge), nitrogen (N), aluminum (Al), yttrium (Y), gadolinium (Gd), or lanthanum (La). Additionally or alternatively, the FE oxide comprises hafnium (Hf), zirconium (Zr), and oxygen (O)— e.g., wherein a stoichiometry of the FE oxide is substantially equal to a stoichiometry of a super lattice of hafnium oxide (HfO) and zirconium oxide (ZrO). For example, a stoichiometry of the FE oxide is substantially equal to that of hafnium oxide (HfO₂), of ZrO₂, or of any of various other suitable binary oxides which, when so doped, exhibit robust ferroelectricity (or antiferroelectricity, in some embodiments). In still another embodiment, a stoichiometry of the FE oxide is substantially equal to a stoichiometry of hafnium zirconium oxide (H₂O) which, for example, is doped with lanthanum (La) or any of various other suitable dopants. In some embodiments, a thickness of the FE oxide is equal to or less than 5 nanometers (nm).

According to various examples, the crossbar memory array 200 may be integrated or otherwise coupled with any of various suitable complimentary metal-oxide-semiconductor (CMOS) circuits (or other suitable computer circuitry) to facilitate a reading of data from, and/or a writing of data to, FE devices 230. This CMOS circuitry may provide additional functionality such as input/output functions, buffering, logic, configuration, or other functionality. In one such embodiment, individual word lines and/or individual bit lines of crossbar memory array 200 may be connected to such CMOS circuitry—e.g., by interconnect structures including the illustrative via 240 shown. The via 240 may be an electrically conductive path through various substrate materials used in manufacturing the crossbar architecture.

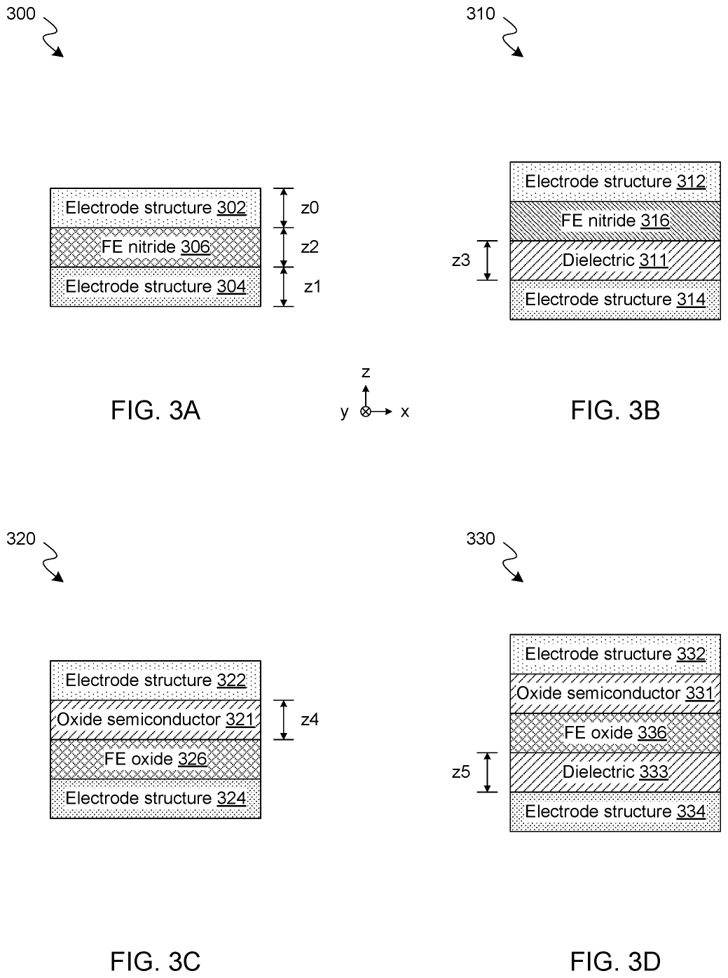

FIGS. 3A through 3D show cross-sectional side views of respective ferroelectric (FE) devices 300, 310, 320, 330 which are each to function as a resistive data storage element of a crossbar memory array according to a corresponding embodiment. FE devices 300, 310, 320, 330 each illustrate a respective embodiment which is operable to selectively provide functionality of a diode. In some embodiments, a given one of FE devices 300, 310, 320, 330 provides functionality such as that of one of cells 122, or of one of FE devices 230.

As shown in FIG. 3A, FE device 300 comprises a layer of a FE nitride 306 and electrode structures 302, 304 which are on opposite respective sides of FE nitride 306. In some embodiments, electrode structures 302, 304 each provide a respective terminal by which FE device 300 is to be coupled to a different respective one of a bit line or a word line of a crossbar memory array (e.g., wherein electrode structures 302, 304 correspond functionally to the first electrode structure and the second electrode structure of FE device 232).

In one such embodiment, a given one of electrode structures 302, 304 comprises any of various suitable metal materials including (but not limited to) titanium (Ti), tungsten (W), tantalum (Ta), Ru), iridium (Ir), aluminum (Al), copper (Cu), cobalt (Co), chromium (Cr), molybdenum (Mo), nickel (Ni), gold (Au), or platinum (Pt), or combinations thereof. For example, a stoichiometry of one such electrode structure is substantially equal to a stoichiometry of TiN, or TaN, in some embodiments.

Additionally or alternatively, a given one of electrode structures 302, 304 comprises any of various suitable oxide semiconductors which include (but are not limited to) indium (In), gallium (Ga), zinc (Zn), tungsten (W), strontium (Sr), titanium (Ti), or combinations thereof. By way of illustration and not limitation, a stoichiometry of a given one of the first electrode structure or the second electrode structure is substantially equal to a stoichiometry of indium gallium zinc oxide (IGZO), indium tungsten oxide (IWO), strontium titanate (STO), or Nb-doped STO (for example).

In various embodiments, FE nitride 306 comprises aluminum (Al), scandium (Sc), nitrogen (N) and, in some embodiments, gallium (Ga)—e.g., wherein a stoichiometry of the FE nitride 306 is substantially equal to a stoichiometry of an aluminum scandium nitride (AlScN) material, such as one wherein a molar percentage of Sc is in a range between 20% to 50%. In an illustrative scenario according to one embodiment, a (z-axis) thickness z0 of electrode structure 302, and/or a thickness z1 of electrode structure 304, is in a range of 5 nanometers (nm) to 30 nm—e.g., wherein a (z-axis) thickness z2 of FE nitride 306 is in a range of 3 nm to 30 nm. However, some or all of the various thicknesses z0, z1, z2 may be different in other embodiments.

As shown in FIG. 3B, FE device 310 comprises electrode structures 312, 314, as well as a layer of a FE nitride 316 and a layer of a dielectric 311, which are variously disposed between electrode structures 312, 314. In an embodiment, electrode structures 312, 314 include some or all of the features of electrode structures 302, 304—e.g., wherein FE nitride 316 includes some or all of the features of FE nitride 306.

In an embodiment, dielectric 311 comprises any of various suitable oxide (or other) insulator materials. By way of illustration and not limitation, dielectric 311 comprises oxygen (O), ruthenium (Ru), iridium (Jr), aluminum (Al), titanium (Ti), indium (In), gallium (Ga), zinc (Zn), tantalum (Ta), lanthanum (La), sodium (Na), niobium (Nb), or combinations thereof. For example, a stoichiometry of dielectric 311 is substantially the same as that of RuO₂, IrO₂, Al₂O₃, TiO₂, IGZO, In₂O₃, Ta₂O₃, La₂O₃, Nb₂O₅, or Na₂O₅. In one example embodiment, a (z-axis) thickness z3 of dielectric 311 is in a range of 5 nm or less—e.g., wherein a thickness of FE nitride 316 is in a range of 3 nm to 30 nm, and wherein respective thicknesses of electrode structures 312, 314 are each in a range of 5 nm to 30 nm.

As shown in FIG. 3C, FE device 320 comprises electrode structures 322, 324, as well as a layer of a FE oxide 326 and a layer of an oxide semiconductor 321, which are variously disposed between electrode structures 322, 324. Electrode structures 322, 324 include some or all of the features of electrode structures 302, 304, for example. In various embodiments, electrode structure 322 is a metal such as any of those described herein with reference to electrode structures 302, 304. By contrast, oxide semiconductor 321 comprises any of various suitable oxide semiconductors such as those described herein with reference to electrode structures 302, 304.

In some embodiments, FE oxide 326 comprises hafnium (Hf), and oxygen (O), as well as any of various dopants including (for example) one of silicon (Si), germanium (Ge), nitrogen (N), aluminum (Al), yttrium (Y), gadolinium (Gd), or lanthanum (La). In one such embodiment, a stoichiometry of FE oxide 326 is substantially equal to that of a doped hafnium oxide (HfO)— e.g., wherein a molar percentage of the dopant(s) in the FE oxide 326 is less than 15%. In another embodiment, FE oxide 326 comprises hafnium (Hf), zirconium (Zr), and oxygen (O)— e.g., wherein a stoichiometry of FE oxide 326 is substantially equal to a stoichiometry of a super lattice of hafnium oxide (HfO) and zirconium oxide (ZrO). In still another embodiment, a stoichiometry of FE oxide 326 is substantially equal to a stoichiometry of hafnium zirconium oxide (H₂O) which, for example, is doped with lanthanum (La) or any of various other suitable dopants—e.g., wherein a molar percentage of the dopant(s) in FE oxide 326 is less than 15%. In one example embodiment, a (z-axis) thickness z4 of oxide semiconductor 321 is in a range of 5 nm to 30 nm—e.g., wherein a thickness of FE oxide 326 is in a range of 5 nm or less, and wherein respective thicknesses of electrode structures 322, 324 are each in a range of 5 nm to 30 nm.

As shown in FIG. 3D, FE device 330 comprises electrode structures 332, 334, as well as a layer of a FE oxide 336, a layer of an oxide semiconductor 331, and a layer of a dielectric 333, which are variously disposed between electrode structures 332, 334. In an embodiment, electrode structures 332, 334 include some or all of the features of electrode structures 322, 324—e.g., wherein FE oxide 336 includes some or all of the features of FE oxide 326, oxide semiconductor 331 includes some or all of the features of oxide semiconductor 321, and/or dielectric 333 includes some or all of the features of dielectric 311. In one example embodiment, a (z-axis) thickness z5 of ‘333 is in a range of 5 nm or less—e.g., wherein a thickness of FE oxide 336 is in a range of 5 nm or less, wherein a thickness of oxide semiconductor 331 is in a range of 5 nm to 30 nm, and wherein respective thicknesses of electrode structures 332, 334 are each in a range of 5 nm to 30 nm.

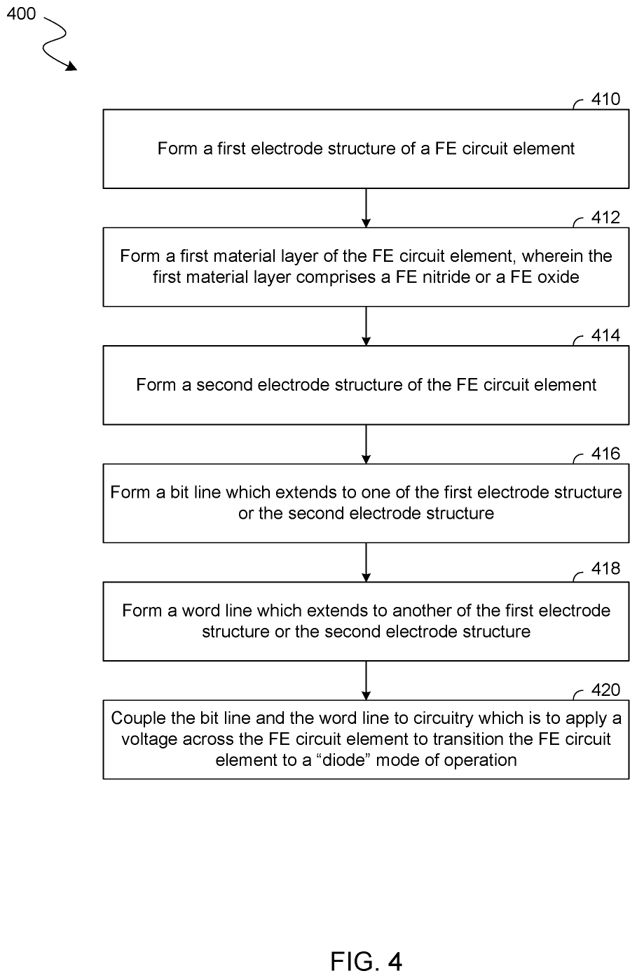

FIG. 4 shows an example of a method 400 for fabricating a memory device according to an embodiment. Method 400 illustrates an embodiment which provides a crossbar memory array—such as memory array 120 or crossbar memory array 200—comprising FE circuit elements that are each to serve as a respective memory cell. For example, one or more such FE circuit elements each include features of one of cells 122, of one of FE devices 230, or of one of FE devices 300, 310, 320, 330.

As shown in FIG. 4, method 400 comprises (at 410) forming a first electrode structure of a FE circuit element. In an embodiment, the forming at 410 comprises one or more pattern, etch, and/or deposition processes such as those which are adapted (for example) from conventional techniques to fabricate structures in or on a device layer—e.g., in a back end of line—of a semiconductor wafer. In one embodiment, the first electrode structure comprises a metal including one of titanium (Ti), tungsten (W), tantalum (Ta), Ru), iridium (Jr), aluminum (Al), copper (Cu), cobalt (Co), chromium (Cr), molybdenum (Mo), nickel (Ni), gold (Au), or platinum (Pt). In another embodiment, the first electrode structure comprises any of various oxide semiconductors which include one of indium (In), gallium (Ga), zinc (Zn), tungsten (W), strontium (Sr), or titanium (Ti).

Method 400 further comprises (at 412) forming a first material layer of the FE circuit element, wherein the first material layer comprises a FE nitride or a FE oxide. In one such embodiment, the first material layer comprises a FE nitride which includes aluminum (Al), scandium (Sc), nitrogen (N) and, in some embodiments, gallium (Ga). In one such embodiment, the first material layer comprises a FE nitride which includes hafnium (Hf), oxygen (O), and one of silicon (Si), germanium (Ge), nitrogen (N), aluminum (Al), yttrium (Y), gadolinium (Gd), or lanthanum (La).

Method 400 further comprises (at 414) forming a second electrode structure of the FE circuit element, wherein the first material layer is between the first electrode structure and the second electrode structure. In one such embodiment, the second electrode structure includes a metal or an oxide semiconductor, such as one of those described herein with respect to the forming at 410.

In various embodiments, wherein the first material layer comprises the FE oxide, and the first electrode structure comprises a metal, method 400 further comprises additional processing (not shown) to form a layer of an oxide semiconductor between the first material layer and the first electrode structure. For example, the oxide semiconductor comprises oxygen (O), and one of indium (In), gallium (Ga), zinc (Zn), tungsten (W), strontium (Sr), or titanium (Ti). In one such embodiment, method 400 further comprises additional processing (not shown) to form a layer of a dielectric between the first material layer and the second electrode structure. For example, the dielectric comprises oxygen (O), and one of ruthenium (Ru), iridium (Jr), aluminum (Al), titanium (Ti), indium (In), gallium (Ga), zinc (Zn), tantalum (Ta), lanthanum (La), niobium (Nb), or sodium (Na).

Method 400 further comprises (at 416) forming a bit line which extends to one of the first electrode structure or the second electrode structure, and further forming a word line (at 418) which extends to another of the first electrode structure or the second electrode structure. Method 400 further comprises (at 420) coupling the bit line and the word line to circuitry (such as row driver circuitry 126, column driver circuitry 128 and, in some embodiments, memory control unit 110) which is to apply a voltage across the FE circuit element, wherein based on the voltage, the FE circuit element is to transition to a mode of operation as a diode. For example, the forming at 416, 418, and 420 includes metallization processing—e.g., adapted from conventional fabrication techniques—to form traces, vias and/or other interconnect structures in a back end of line of a semiconductor wafer.

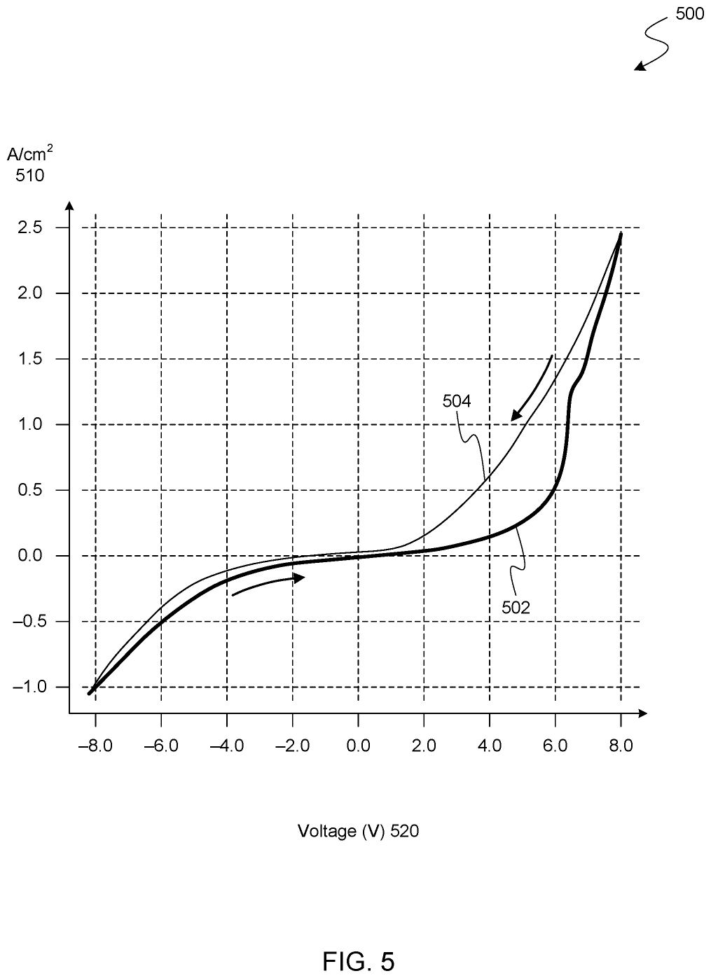

FIG. 5 shows a graph 500 illustrating current conduction by a FE circuit element of a cross bar memory array according to an embodiment. Graph 500 illustrates characteristics of a FE circuit element—e.g., in one of cells 122, one of FE devices 230, or one of FE device 300, 310, 320, 330— which is operable to selectively provide functionality of a diode.

As shown by plots 502, 504, the FE circuit element is operable in a first voltage range—in this example, a range of −2.0 Volts (V) to 8.0 V, approximately—which corresponds to a “diode” mode of operation of the FE circuit element. Additionally or alternatively, the FE circuit element is operable in a second voltage range—in this example, a range of −2.0 V to −8.0 V, approximately—which corresponds to an “off” mode of operation of the FE circuit element. In an embodiment, a difference between plots 502, 504—e.g., at least in the first voltage range—is provided at least in part by the use of different respective materials for electrode structures of the FE circuit element.

In various embodiments, these “diode” and “off” modes are variously (re)configurable due at least in part on an ability of the FE circuit element to selectively provide (or prevent) a PN junction at an interface between a FE material (e.g., a FE oxide or a FE nitride) and a doped semiconductor. In one such embodiment, a barrier height for electron conduction by the FE circuit element is modulated by the polarization direction. Accordingly, a high current can be obtained by applying one bias polarity to the FE circuit element while is has a corresponding polarization direction. By contrast, little or no current is conducted where the FE circuit element is either not selected (due to a different bias polarity), or is in an off state (due to a different polarization direction).

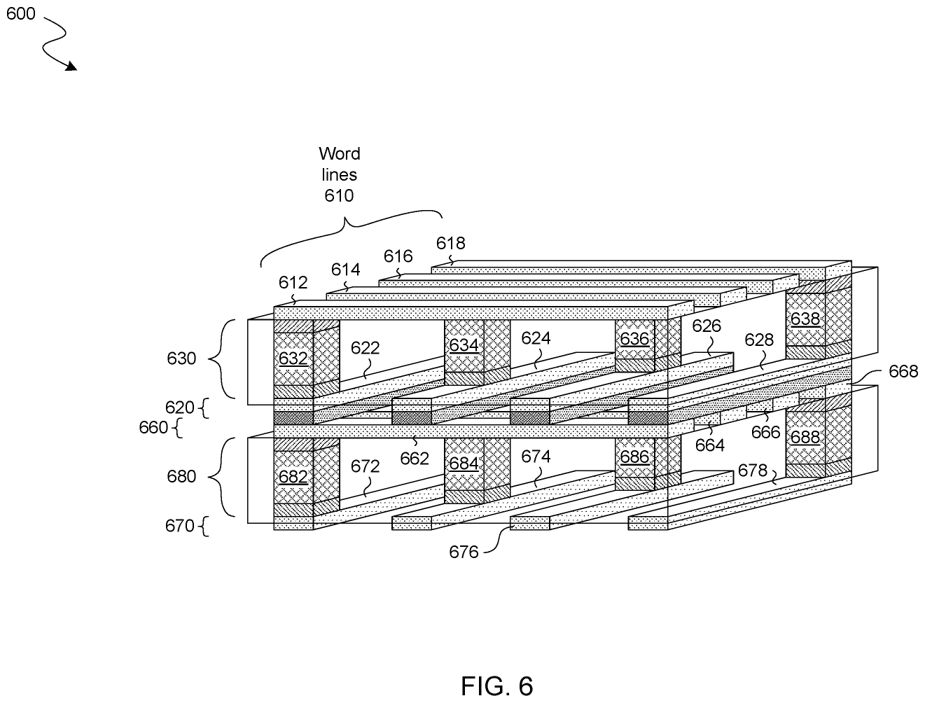

FIG. 6 shows a cut-away perspective view of a multi-layer memory device 600 according to another embodiment. Memory device 600 illustrates an example of an embodiment which comprises multiple layers of crossbar memory arrays, some or all of which each comprise a respective FE circuit element which is (re)configurable to selectively provide functionality of a diode. In one such embodiment, memory device 600 provides functionality such as that of memory array 120, or of crossbar memory array 200—e.g., wherein memory device 600 comprises one of FE devices 300, 310, 320, 330, and/or wherein structures of memory device 600 are provided according to method 400.

As shown in FIG. 6, memory device 600 comprises a first crossbar memory array and a second crossbar memory array which is vertically offset from the first crossbar memory array. The first crossbar memory array comprises a set of word lines 610 and a set of bit lines 620 which (for example) correspond functionally to word lines 210 and bit lines 220 (respectively). Programmable FE circuit elements 630 of memory device 600 are variously located at corresponding cross points which are each between a respective one of word lines 610 and a respective one of bit lines 620. By way of illustration and not limitation, a FE device 632 is at a cross point between a word line 612 and a bit line 622—e.g., wherein another FE device 634 is at a cross point between a word line 614 and a bit line 624. Furthermore, a FE device 636 is at a cross point between a word line 616 and a bit line 626, wherein another FE device 638 is at a cross point between a word line 618 and a bit line 628. The FE circuit elements 630 are each to function as a resistive memory element—e.g., wherein some or all of FE circuit elements 630 are variously (re)configurable each to selectively provide functionality of a diode. In one such embodiment, a given one of FE circuit elements 630 comprises some or all of the features of one of FE devices 300, 310, 320, 330 (for example).

In one such embodiment the second crossbar memory array comprises another set of word lines 660 and another set of bit lines 670—e.g., corresponding functionally to word lines 210 and bit lines 220 (respectively). Dielectric structures are variously provided—between bit lines 620 and word lines 660—to at least partially insulate the first crossbar memory array and the second crossbar memory array from each other. Programmable FE circuit elements 680 of memory device 600 are variously located at corresponding cross points which are each between a respective one of word lines 660 and a respective one of bit lines 670. By way of illustration and not limitation, a FE device 682 is at a cross point between a word line 662 and a bit line 672—e.g., wherein another FE device 684 is at a cross point between a word line 664 and a bit line 674. Furthermore, a FE device 686 is at a cross point between a word line 666 and a bit line 676, wherein another FE device 688 is at a cross point between a word line 668 and a bit line 678. The FE circuit elements 680 are each to function as a resistive memory element—e.g., wherein some or all of FE circuit elements 680 are variously (re)configurable each to selectively provide functionality of a diode.

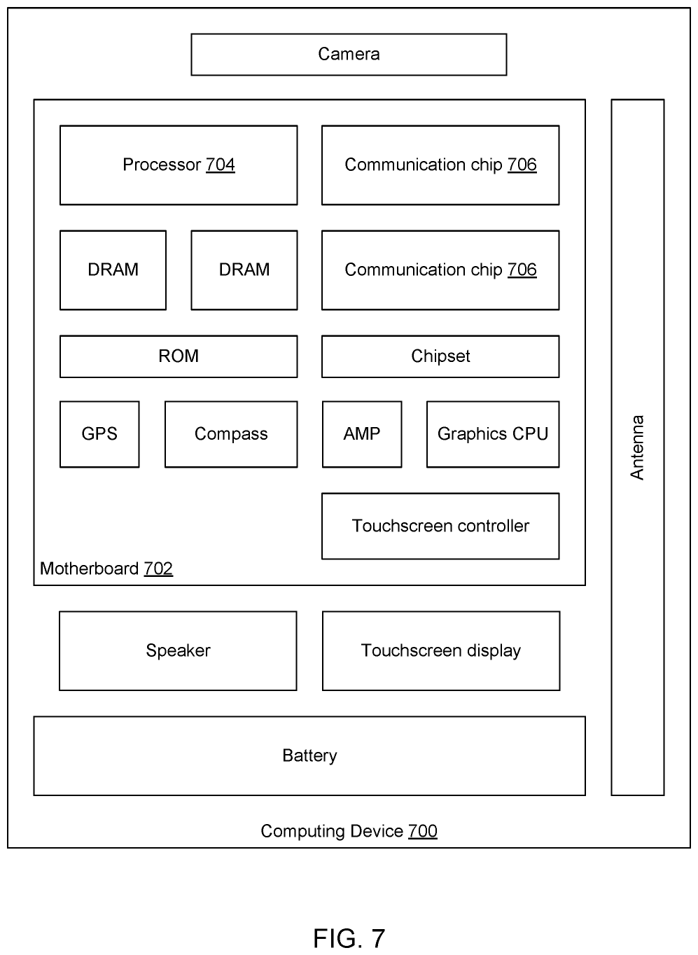

FIG. 7 illustrates a computing device 700 in accordance with one embodiment. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. The term “processor” may refer to any device or portion of a device that processes electronic data from registers and/or memory to transform that electronic data into other electronic data that may be stored in registers and/or memory. The communication chip 706 also includes an integrated circuit die packaged within the communication chip 706.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

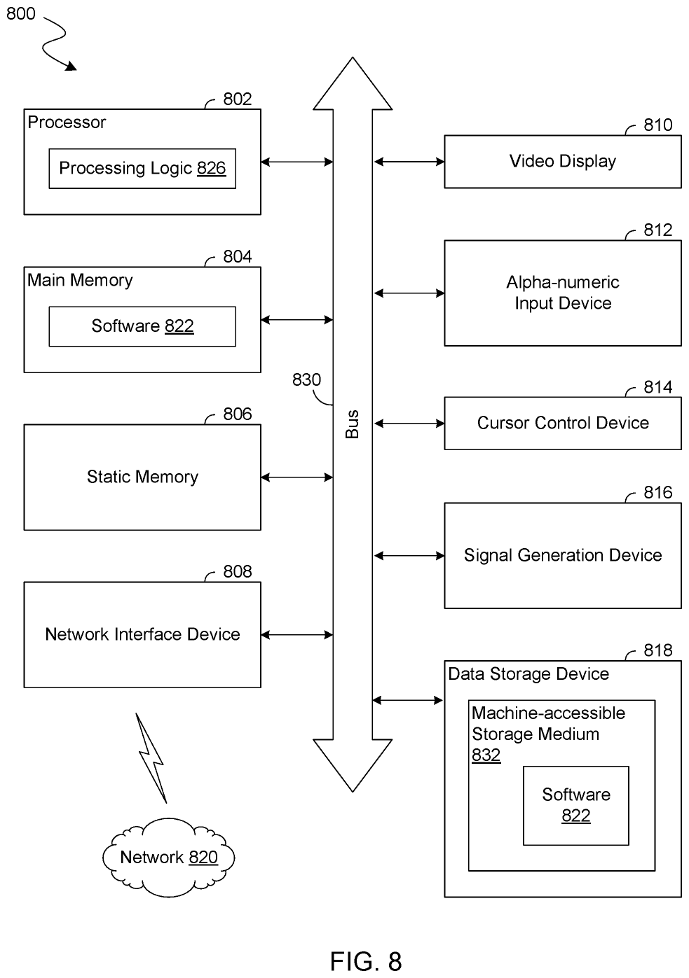

FIG. 8 illustrates a diagrammatic representation of a machine in the exemplary form of a computer system 800 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 800 includes a processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

Processor 802 represents one or more general-purpose processing devices such as a microprocessor, central processing unit, or the like. More particularly, the processor 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 802 may also be one or more special-purpose processing devices such as an application specific integrated circuit (ASIC), a field programmable gate array (FPGA), a digital signal processor (DSP), network processor, or the like. Processor 802 is configured to execute the processing logic 826 for performing the operations described herein.

The computer system 800 may further include a network interface device 808. The computer system 800 also may include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium (or more specifically a computer-readable storage medium) 832 on which is stored one or more sets of instructions (e.g., software 822) embodying any one or more of the methodologies or functions described herein. The software 822 may also reside, completely or at least partially, within the main memory 804 and/or within the processor 802 during execution thereof by the computer system 800, the main memory 804 and the processor 802 also constituting machine-readable storage media. The software 822 may further be transmitted or received over a network 820 via the network interface device 808.

While the machine-accessible storage medium 832 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

In the following description, numerous details are discussed to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

In one or more first embodiments, a device comprises a crossbar memory array comprising a ferroelectric (FE) circuit element comprising a first electrode structure, a first material layer comprising a FE nitride or a FE oxide, and a second electrode structure, wherein the first material layer is between the first electrode structure and the second electrode structure, a bit line which extends to one of the first electrode structure or the second electrode structure, a word line which extends to another of the first electrode structure or the second electrode structure, circuitry, coupled to the crossbar memory array, which is to apply a voltage across the FE circuit element, wherein based on the voltage, the FE circuit element is to transition to a mode of operation as a diode.

In one or more second embodiments, further to the first embodiment, the first material layer comprises the FE nitride.

In one or more third embodiments, further to the second embodiment, the FE nitride comprises aluminum (Al), scandium (Sc), and nitrogen (N).

In one or more fourth embodiments, further to the third embodiment, a thickness of one of the first electrode structure or the second electrode structure is in a range of 5 nanometers (nm) to 30 nm, and wherein a thickness of the FE nitride is in a range of 3 nm to 30 nm.

In one or more fifth embodiments, further to the second embodiment, the FE circuit element further comprises a layer of a dielectric between the first material layer and the first electrode structure.

In one or more sixth embodiments, further to the fifth embodiment, the dielectric comprises oxygen (O), and one of ruthenium (Ru), iridium (Jr), aluminum (Al), titanium (Ti), indium (In), gallium (Ga), zinc (Zn), tantalum (Ta), lanthanum (La), or sodium (Na).

In one or more seventh embodiments, further to the first embodiment, the first material layer comprises the FE oxide, and wherein the first electrode structure comprises a metal, the FE circuit element further comprises a layer of an oxide semiconductor between the first material layer and the first electrode structure.

In one or more eighth embodiments, further to the seventh embodiment, the FE oxide comprises hafnium (Hf), oxygen (O), and one of silicon (Si), germanium (Ge), nitrogen (N), aluminum (Al), yttrium (Y), gadolinium (Gd), or lanthanum (La), and the oxide semiconductor comprises oxygen (O), and one of indium (In), gallium (Ga), zinc (Zn), tungsten (W), strontium (Sr), or titanium (Ti).

In one or more ninth embodiments, further to the eighth embodiment, the FE circuit element comprises a layer of a dielectric between the first material layer and the second electrode structure.

In one or more tenth embodiments, further to the ninth embodiment, the dielectric comprises oxygen (O), and one of ruthenium (Ru), iridium (Jr), aluminum (Al), titanium (Ti), indium (In), gallium (Ga), zinc (Zn), tantalum (Ta), lanthanum (La), or sodium (Na).

In one or more eleventh embodiments, a method comprises forming a first electrode structure of a ferroelectric (FE) circuit element, forming a first material layer of the FE circuit element, wherein the first material layer comprises a FE nitride or a FE oxide, forming a second electrode structure of the FE circuit element, wherein the first material layer is between the first electrode structure and the second electrode structure, forming a bit line which extends to one of the first electrode structure or the second electrode structure, forming a word line which extends to another of the first electrode structure or the second electrode structure, and coupling the bit line and the word line to circuitry which is to apply a voltage across the FE circuit element, wherein based on the voltage, the FE circuit element is to transition to a mode of operation as a diode.

In one or more twelfth embodiments, further to the eleventh embodiment, the first material layer comprises the FE nitride.

In one or more thirteenth embodiments, further to the twelfth embodiment, the FE nitride comprises aluminum (Al), scandium (Sc), and nitrogen (N).

In one or more fourteenth embodiments, further to the thirteenth embodiment, a thickness of one of the first electrode structure or the second electrode structure is in a range of 5 nanometers (nm) to 30 nm, and wherein a thickness of the FE nitride is in a range of 3 nm to 30 nm.

In one or more fifteenth embodiments, further to the twelfth embodiment, the method further comprises forming a layer of a dielectric between the first material layer and the first electrode structure.

In one or more sixteenth embodiments, further to the fifteenth embodiment, the dielectric comprises oxygen (O), and one of ruthenium (Ru), iridium (Jr), aluminum (Al), titanium (Ti), indium (In), gallium (Ga), zinc (Zn), tantalum (Ta), lanthanum (La), or sodium (Na).

In one or more seventeenth embodiments, further to the eleventh embodiment, the first material layer comprises the FE oxide, and wherein the first electrode structure comprises a metal, the method further comprises forming a layer of an oxide semiconductor between the first material layer and the first electrode structure.

In one or more eighteenth embodiments, further to the seventeenth embodiment, the FE oxide comprises hafnium (Hf), oxygen (O), and one of silicon (Si), germanium (Ge), nitrogen (N), aluminum (Al), yttrium (Y), gadolinium (Gd), or lanthanum (La), and the oxide semiconductor comprises oxygen (O), and one of indium (In), gallium (Ga), zinc (Zn), tungsten (W), strontium (Sr), or titanium (Ti).

In one or more nineteenth embodiments, further to the eighteenth embodiment, the method further comprises forming a layer of a dielectric between the first material layer and the second electrode structure.

In one or more twentieth embodiments, further to the nineteenth embodiment, the dielectric comprises oxygen (O), and one of ruthenium (Ru), iridium (Jr), aluminum (Al), titanium (Ti), indium (In), gallium (Ga), zinc (Zn), tantalum (Ta), lanthanum (La), or sodium (Na).

In one or more twenty-first embodiments, a system comprises a microprocessor comprising circuitry to execute an instruction, a memory device coupled to the microprocessor, the memory device comprising a crossbar memory array comprising a ferroelectric (FE) circuit element comprising a first electrode structure, a first material layer comprising a FE nitride or a FE oxide, and a second electrode structure, wherein the first material layer is between the first electrode structure and the second electrode structure, a bit line which extends to one of the first electrode structure or the second electrode structure, a word line which extends to another of the first electrode structure or the second electrode structure, circuitry, coupled to the crossbar memory array, which is to apply a voltage across the FE circuit element, wherein based on the voltage, the FE circuit element is to transition to a mode of operation as a diode.

In one or more twenty-second embodiments, further to the twenty-first embodiment, the first material layer comprises the FE nitride.

In one or more twenty-third embodiments, further to the twenty-second embodiment, the FE nitride comprises aluminum (Al), scandium (Sc), and nitrogen (N).

In one or more twenty-fourth embodiments, further to the twenty-third embodiment, a thickness of one of the first electrode structure or the second electrode structure is in a range of 5 nanometers (nm) to 30 nm, and wherein a thickness of the FE nitride is in a range of 3 nm to 30 nm.

In one or more twenty-fifth embodiments, further to the twenty-second embodiment, the FE circuit element further comprises a layer of a dielectric between the first material layer and the first electrode structure.

In one or more twenty-sixth embodiments, further to the twenty-fifth embodiment, the dielectric comprises oxygen (O), and one of ruthenium (Ru), iridium (Jr), aluminum (Al), titanium (Ti), indium (In), gallium (Ga), zinc (Zn), tantalum (Ta), lanthanum (La), or sodium (Na).

In one or more twenty-seventh embodiments, further to the twenty-first embodiment, the first material layer comprises the FE oxide, and wherein the first electrode structure comprises a metal, the FE circuit element further comprises a layer of an oxide semiconductor between the first material layer and the first electrode structure.

In one or more twenty-eighth embodiments, further to the twenty-seventh embodiment, the FE oxide comprises hafnium (Hf), oxygen (O), and one of silicon (Si), germanium (Ge), nitrogen (N), aluminum (Al), yttrium (Y), gadolinium (Gd), or lanthanum (La), and the oxide semiconductor comprises oxygen (O), and one of indium (In), gallium (Ga), zinc (Zn), tungsten (W), strontium (Sr), or titanium (Ti).

In one or more twenty-ninth embodiments, further to the twenty-eighth embodiment, the FE circuit element comprises a layer of a dielectric between the first material layer and the second electrode structure.

In one or more thirtieth embodiments, further to the twenty-ninth embodiment, the dielectric comprises oxygen (O), and one of ruthenium (Ru), iridium (Jr), aluminum (Al), titanium (Ti), indium (In), gallium (Ga), zinc (Zn), tantalum (Ta), lanthanum (La), or sodium (Na).

Techniques and architectures for providing functionality of a resistive memory device are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A device comprising:
a crossbar memory array comprising:
a ferroelectric (FE) circuit element comprising:
a first electrode structure;
a first material layer comprising a FE nitride or a FE oxide; and
a second electrode structure, wherein the first material layer is between the first electrode structure and the second electrode structure;
a bit line which extends to one of the first electrode structure or the second electrode structure;
a word line which extends to another of the first electrode structure or the second electrode structure;
circuitry, coupled to the crossbar memory array, which is to apply a voltage across the FE circuit element, wherein based on the voltage, the FE circuit element is to transition to a mode of operation as a diode.

2. The device of claim 1, wherein the first material layer comprises the FE nitride.

3. The device of claim 2, wherein the FE nitride comprises aluminum (Al), scandium (Sc), and nitrogen (N).

4. The device of claim 3, wherein a thickness of one of the first electrode structure or the second electrode structure is in a range of 5 nanometers (nm) to 30 nm, and wherein a thickness of the FE nitride is in a range of 3 nm to 30 nm.

5. The device of claim 2, the FE circuit element further comprising a layer of a dielectric between the first material layer and the first electrode structure.

6. The device of claim 5, wherein the dielectric comprises oxygen (O), and one of ruthenium (Ru), iridium (Ir), aluminum (Al), titanium (Ti), indium (In), gallium (Ga), zinc (Zn), tantalum (Ta), lanthanum (La), or sodium (Na).

7. The device of claim 1, wherein the first material layer comprises the FE oxide, and wherein the first electrode structure comprises a metal, the FE circuit element further comprising:
a layer of an oxide semiconductor between the first material layer and the first electrode structure.

8. The device of claim 7, wherein:
the FE oxide comprises hafnium (Hf), oxygen (O), and one of silicon (Si), germanium (Ge), nitrogen (N), aluminum (Al), yttrium (Y), gadolinium (Gd), or lanthanum (La); and
the oxide semiconductor comprises oxygen (O), and one of indium (In), gallium (Ga), zinc (Zn), tungsten (W), strontium (Sr), or titanium (Ti).

9. The device of claim 8, the FE circuit element comprising a layer of a dielectric between the first material layer and the second electrode structure.

10. The device of claim 9, wherein the dielectric comprises oxygen (O), and one of ruthenium (Ru), iridium (Ir), aluminum (Al), titanium (Ti), indium (In), gallium (Ga), zinc (Zn), tantalum (Ta), lanthanum (La), or sodium (Na).

11. A method comprising:
forming a first electrode structure of a ferroelectric (FE) circuit element;
forming a first material layer of the FE circuit element, wherein the first material layer comprises a FE nitride or a FE oxide;
forming a second electrode structure of the FE circuit element, wherein the first material layer is between the first electrode structure and the second electrode structure;
forming a bit line which extends to one of the first electrode structure or the second electrode structure;
forming a word line which extends to another of the first electrode structure or the second electrode structure; and
coupling the bit line and the word line to circuitry which is to apply a voltage across the FE circuit element, wherein based on the voltage, the FE circuit element is to transition to a mode of operation as a diode.

12. The method of claim 11, wherein the first material layer comprises the FE nitride.

13. The method of claim 12, wherein the FE nitride comprises aluminum (Al), scandium (Sc), and nitrogen (N).

14. The method of claim 12, further comprising forming a layer of a dielectric between the first material layer and the first electrode structure.

15. The method of claim 11, wherein the first material layer comprises the FE oxide, and wherein the first electrode structure comprises a metal, the method further comprising:
forming a layer of an oxide semiconductor between the first material layer and the first electrode structure.

16. The method of claim 15, wherein:
the FE oxide comprises hafnium (Hf), oxygen (O), and one of silicon (Si), germanium (Ge), nitrogen (N), aluminum (Al), yttrium (Y), gadolinium (Gd), or lanthanum (La); and
the oxide semiconductor comprises oxygen (O), and one of indium (In), gallium (Ga), zinc (Zn), tungsten (W), strontium (Sr), or titanium (Ti).

17. A system comprising:
a microprocessor comprising circuitry to execute an instruction;
a memory device coupled to the microprocessor, the memory device comprising:
a crossbar memory array comprising:
a ferroelectric (FE) circuit element comprising:
a first electrode structure;
a first material layer comprising a FE nitride or a FE oxide; and
a second electrode structure, wherein the first material layer is between the first electrode structure and the second electrode structure;
a bit line which extends to one of the first electrode structure or the second electrode structure;
a word line which extends to another of the first electrode structure or the second electrode structure;
circuitry, coupled to the crossbar memory array, which is to apply a voltage across the FE circuit element, wherein based on the voltage, the FE circuit element is to transition to a mode of operation as a diode.

18. The system of claim 17, wherein the first material layer comprises the FE nitride.

19. The system of claim 18, wherein the FE nitride comprises aluminum (Al), scandium (Sc), and nitrogen (N).

20. The system of claim 17, wherein the first material layer comprises the FE oxide, and wherein the first electrode structure comprises a metal, the FE circuit element further comprising:
a layer of an oxide semiconductor between the first material layer and the first electrode structure.
